(19) United States
(12) Patent Application Publication
(10) Pub. No.: US 2004/0076044 A1
(43) Pub. Date: Apr. 22, 2004

(54) Method and system for improving access latency of multiple bank devices

(76) Inventor: Farshid Nowshadi, Beds (GB)

Correspondence Address: HUNTON & WILLIAMS LLP, INTELLECTUAL PROPERTY DEPARTMENT, 1900 K STREET, N.W., SUITE 1200, WASHINGTON, DC, 20006-1109, US

(21) Appl. No.: 10/615,384

(22) Filed: Jul. 9, 2003

Related U.S. Application Data
(60) Provisional application No. 60/394,237, filed on Jul. 9, 2002.

(51) Int. Cl. G11C 7/00

(52) U.S. Cl. 365/200

(57) ABSTRACT

The present invention is directed to a technique for improving access latency of multiple bank DRAMs. According to an embodiment of the present invention, address lines may be swapped to improve DRAM access latency and performance. According to another embodiment of the present invention, SDRAM performance may be improved by increasing the likelihood that cycles may be interleaved thereby reducing the overhead associated with opening and closing banks. The aspects of the present invention may be applied to multiple bank DRAM, such as SDRAM, DDR devices and/or other shared resource, in accordance with the present invention.

### CROSS-REFERENCE TO RELATED APPLICATIONS

This patent application claims priority to U.S. Provisional Patent Application No. 60/394,237 filed Jul. 9, 2002, which is hereby incorporated by reference herein in its entirety.

### FIELD OF THE INVENTION

The present invention relates generally to improving access latency and, more particularly, to improving access latency of multiple bank Dynamic Random Access Memory (DRAM) devices.

### BACKGROUND OF THE INVENTION

Many modern high performance systems have multiple processors, many of which run independently but ultimately share one large common memory pool. Each processor typically has a small amount of fast local Random Access Memory (RAM). A large memory pool including DRAM (as well as Synchronous Dynamic Random Access Memory (SDRAM) or other shared resource) is usually shared amongst most or all the processors within a system.

DRAM bandwidth is very limited. Further, the access time of DRAMs is very slow, much slower than the bandwidth required for a single Central Processing Unit (CPU) let alone two or more CPUs. SDRAM memory devices (as well as other memory devices) are usually made up of two or four internal banks. Two bank devices are becoming increasing rare with the vast majority of SDRAM devices having four banks. Each bank is in effect a miniature DRAM device in its own right.

Although the potential of interleaving banks is a performance boost, it may have some limitations. Generally, only accesses to different banks can be interleaved. If all the accesses are targeted at the same bank, the accesses can not be interleaved. Rather, the accesses are executed in sequence one after another. Therefore, interleaving is generally possible between accesses directed to different banks.

Traditional techniques for mapping a virtual address to a physical address of SDRAMs generally means that it is quite likely that certain banks may get accessed far more than other banks thereby reducing the advantages of interleaving across banks. This is because code and data structures may tend to be concentrated in a small part of a total memory, perhaps contained within a few megabytes, small enough to fit within a single bank. Consequently, CPUs tend to continually access a relatively small area of the DRAM. Repeated accesses to the same area would in turn mean repeated access to the same bank. As a result, the use of interleaving cycles may be hindered thereby reducing performance.

Therefore, there is a need for a technique for improving access latency of multiple bank DRAMs (or other shared resource).

### SUMMARY OF THE INVENTION

Aspects of the present invention overcome the problems noted above, and realize additional advantages. In one exemplary embodiment, a technique for improving access latency of multiple bank DRAMs is disclosed. According to an embodiment of the present invention, address lines may be changed (or swapped) to improve DRAM access latency and performance. According to another embodiment of the present invention, SDRAM performance may be improved by increasing the likelihood that cycles may be interleaved thereby reducing the overhead associated with opening and closing banks. The aspects of the present invention may be applied to a multiple bank DRAM, such as SDRAM or Double Data Rate (DDR) devices and/or other shared resource, in accordance with the present invention.

According to one particular exemplary embodiment, a method for improving access latency of multiple bank devices comprises the steps of identifying a plurality of different memory banks of a shared resource; identifying a logical memory address map of a processor accessing the shared resource; and mapping the logical memory address map to a shared resource address map wherein each memory address of the logical memory address is distributed through the plurality of different memory banks.

In accordance with other aspects of this particular exemplary embodiment of the present invention, each memory address of the logical memory address map accesses each of the plurality of memory banks; each access of each of the plurality of different memory banks overlaps each other; bursting cycles are not interfered; the bursting cycles include efficient transfers of small sequential streams of data to a same memory bank; interleave accesses are improved; the plurality of memory banks comprise at least four different memory banks; the shared resource comprises one or more of DRAM, SDRAM and DDR; the step of mapping further comprises the step of exchanging higher order address lines with mid-order address lines; and the processor's local code is spread across the plurality of memory banks.

According to another particular exemplary embodiment, a system for improving access latency of multiple bank devices comprises an identifying memory banks module for identifying a plurality of different memory banks of a shared resource; an identifying address map module for identifying a logical memory address map of a processor accessing the shared resource; and a mapping module for mapping the logical memory address map to a shared resource address map wherein each memory address of the logical memory address is distributed through the plurality of different memory banks.

The accompanying drawings, which are incorporated in and constitute a part of this specification, illustrate various embodiments of the invention and, together with the description, serve to explain the principles of the invention.

### BRIEF DESCRIPTION OF THE DRAWINGS

The present invention can be understood more completely by reading the following Detailed Description of the Invention, in conjunction with the accompanying drawings, in which:

FIG. 1 is an example of a sequential nature of accessing the same bank.

FIG. 2 is an example of overlapping accesses to different banks, in accordance with an embodiment of the present invention.

FIG. 3A illustrate a sequence without interleaving and FIG. 3B illustrates a sequence with interleaving, in accordance with an embodiment of the present invention.

FIG. 4A illustrate a sequence without interleaving and FIG. 4B illustrates a sequence with interleaving, in accordance with an embodiment of the present invention.

FIG. 5 is an example of an address structure of a SDRAM.

FIG. 6 is an example of a memory map between a processor and a shared resource.

FIG. 7 is an example of a memory map between a processor and a shared resource in accordance with an embodiment of the present invention.

FIG. 8 is an exemplary flowchart illustrating a method for improving access latency, in accordance with an embodiment of the present invention.

FIG. 9 is a diagram illustrating a system for improving access latency, in accordance with an embodiment of the present invention.

FIG. 10 is a schematic diagram of a hardware architecture in which the inventive aspects of the present invention may be incorporated.

FIG. 11 is a schematic diagram of a hardware architecture in which the inventive aspects of the present invention may be incorporated.

FIG. 12 is a schematic diagram of a hardware architecture in which the inventive aspects of the present invention may be incorporated.

FIG. 13 is a schematic diagram of a hardware architecture in which the inventive aspects of the present invention may be incorporated.

FIG. 14 is a schematic diagram of a hardware architecture in which the inventive aspects of the present invention may be incorporated.

FIG. 15 is a schematic diagram of a hardware architecture in which the inventive aspects of the present invention may be incorporated.

### DETAILED DESCRIPTION OF THE INVENTION

The following description is intended to convey a thorough understanding of the invention by providing a number of specific embodiments and details related to access latency. It is understood, however, that the invention is not limited to these specific embodiments and details, which are exemplary only. It is further understood that one possessing ordinary skill in the art, in light of known systems and methods, would appreciate the use of the invention for its intended purposes and benefits in any number of alternative embodiments, depending upon specific design and other needs.

SDRAM memory devices are usually made up of two, four or other number of internal banks. Having multiple banks within a single package allows some or all of these banks to be accessed in parallel thereby improving performance. For instance, while data is being read out of one bank, a new address may be issued to another bank thereby improving interleaving cycles and reducing overhead associated with setting up addresses and/or other tasks. In addition, the bandwidth of the SDRAM may be significantly improved by an optimal use of a bank interleaving feature of an embodiment of the present invention.

According to an embodiment of the present invention, a technique for improving access latency of multiple bank DRAMs is disclosed. For example, address lines may be changed (e.g., swapped) to improve DRAM access latency and performance. According to another embodiment of the present invention, SDRAM performance may be improved by increasing the likelihood that cycles may be interleaved thereby reducing overhead associated with opening and closing banks. The aspects of the present invention may be applied to SDRAM, DDR, and/or other shared resource, in accordance with various embodiments of the present invention.

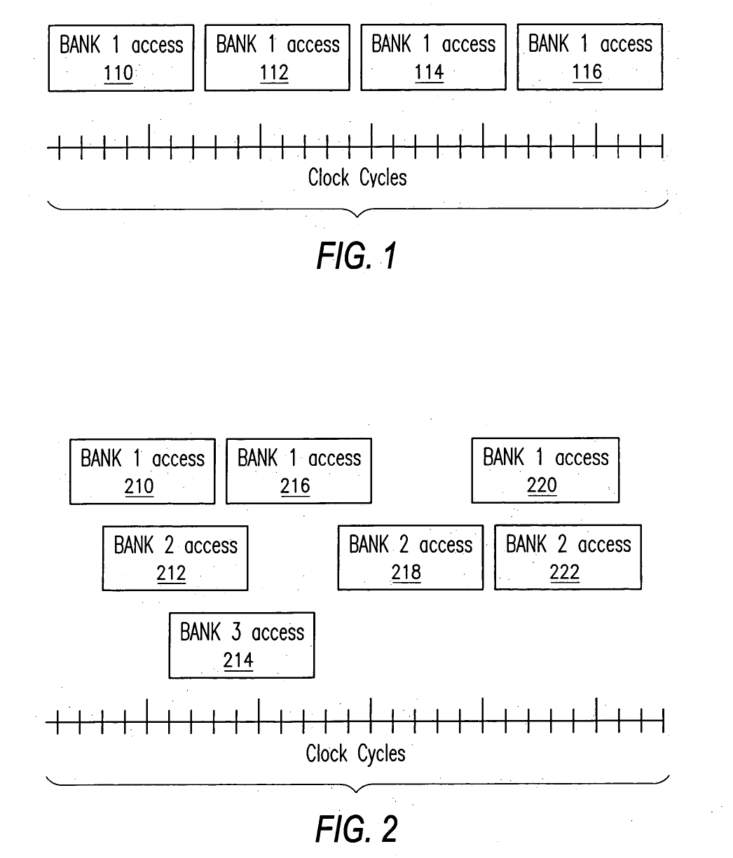

FIG. 1 is an example of a sequential nature of accessing the same bank (e.g., Bank 1). In this example, interleaving is not possible since the same bank is accessed, as shown by 110, 112, 114 and 116. FIG. 2 is an example demonstrating the potential of overlapping accesses to different banks (e.g., Bank 1, Bank 2 and Bank 3). In this example, accesses to Bank 1, Bank 2 and Bank 3 overlap each other. In particular, Bank 1 (210), Bank 2 (212) and Bank 3 (214) are accessed in sequence. Then, Bank 1 (216) is accessed again followed by Bank 2 (218). Next, Bank 1 (220) is re-accessed, followed by Bank 2 (222).

The examples of FIG. 1 and FIG. 2 demonstrate that for optimum performance, adjacent accesses should be addressed to different banks, as recognized by an embodiment of the present invention. Accesses to different banks may overlap to enable the accesses to complete quicker than if they were executed one after another. For example, as shown in FIG. 1, for a particular time frame, Bank 1 may be accessed four times in sequence. In the example of FIG. 2, Bank 1 may be accessed three times, Bank 2 may be accessed three times and Bank 3 may be accessed once, all within substantially the same time frame.

Interleaving improves bandwidth efficiency by exploiting the use of opening multiple banks within the SDRAM device, for example. Efficiency may be dependant on the type of traffic, e.g., whether it was bursty or not. Further, efficiency may be based on location of data. By careful organization of where data is placed into the memory map, significant improvements in performance may be achieved.

Interleaving may also impact and improve latency. Latency of any access is not necessarily just the number of cycles to issue a Row Address Strobe (RAS) and Column Address Strobe (CAS) but more significantly the arbitration delay. In loaded systems, for example, the arbitration delay may be more than the RAS/CAS delay. As interleaving may reduce the arbitration delay, the overall latency may also be reduced.

Pattern interleaving considers and optimizes possibilities in interleaving multiple bank streams into a single one. According to an example, the interleaving process may be overruled by considerations to arbitration and data coherency priorities.

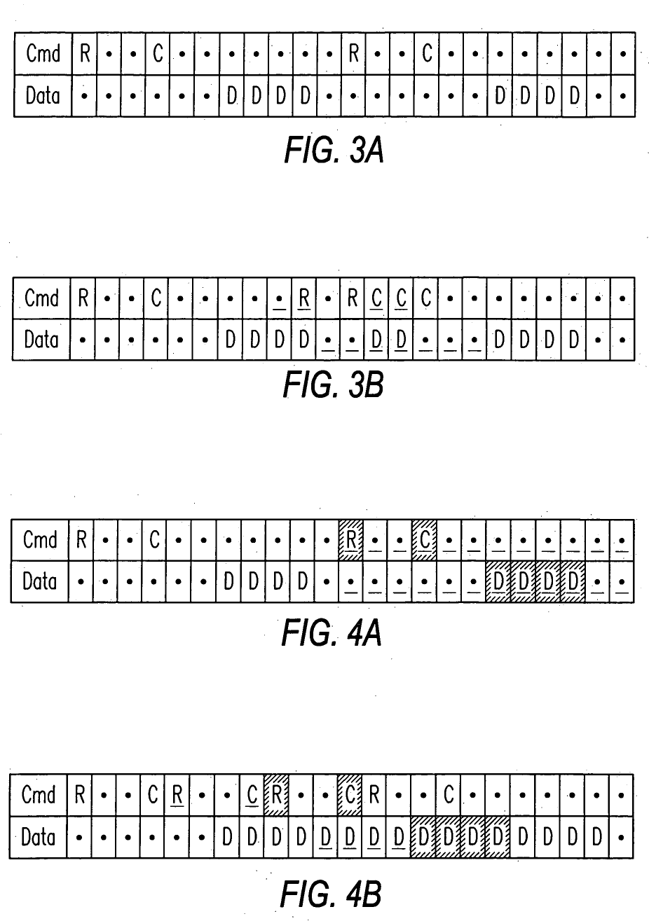

FIGS. 3A and 3B illustrate a write cycle that may be slotted in between two read cycles and FIGS. 4A and 4B illustrate how read cycles may overlap. Bus cycles used to access SDRAM (or other device) for a memory read may include RAS cycles, idle cycles, CAS cycles, idle cycles, and data cycles. In particular, RAS is represented by “R” and provides the upper (e.g., more significant) bits of memory address to be accessed. CAS is represented by “C” and provides the lower (e.g., less significant) bits of the first memory address to be accessed. Data cycles are represented by “D” where for a memory read, the memory device may issue one word of data in each cycle, incrementing the memory address each time. The sequence is similar for a memory write cycle with the exception that the processor provides data to be written with each CAS cycle where there is a CAS cycle for each word. Interleaving exploits the idle cycles in a read/write sequence to one memory bank, using them to issue a command to a different memory bank.

FIG. 3A illustrate a sequence without interleaving and FIG. 3B illustrates a sequence with interleaving. FIG. 3A illustrates a typical sequence of two back-to-back random read cycle to the same bank. Without interleaving, the second access must wait until the first access is finished before the second access starts. With interleaving, a write sequence (as shown with underlining) may occur invisibly in middle of the two read sequences, of FIG. 3B. The write cycle has no impact on the read cycles. This hidden write cycle is possible because it is written to a different bank.

FIG. 4A illustrate a sequence without interleaving and FIG. 4B illustrates a sequence with interleaving. The underlined text represents an access to a different bank. Without interleaving, access to a different bank is made after access to another bank. With interleaving, the bank assesses may be overlapped, thereby improving the efficiency. According to this example, four random reads have occurred in the same time as two random reads without interleaving. Further, the latency experienced by the cycles has been reduced by approximately seven clock ticks, in this example.

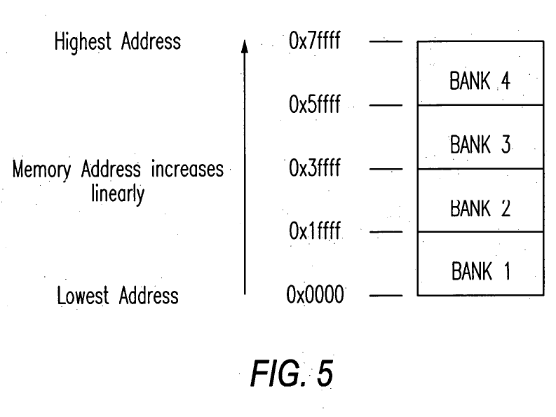

FIG. 5 is an example of an address structure of a SDRAM. An address structure in SDRAMs may include a first bank sitting in a bottom quarter of memory, a second bank sitting in a second quarter of the memory, a third bank sitting in a third quarter of memory and a fourth bank sitting in a top quarter of memory, for example. As shown in FIG. 5, a lowest address may increase linearly, from Bank 1 to Bank 4.

According to an embodiment of the present invention, an address weaving technique may be implemented. Instead of wiring up address lines to a SDRAM linearly such that address increments are linear through the banks, address lines may be changed or swapped. For example, high order address lines may be exchanged with mid-order address lines. As a result, a linear logical address map is distributed so that the CPU (or other processor) may see across a plurality of banks (e.g., all 4 banks) within the SDRAMs (or other shared resource). This makes it more likely that the CPUs running local code (or other function) will access different banks.

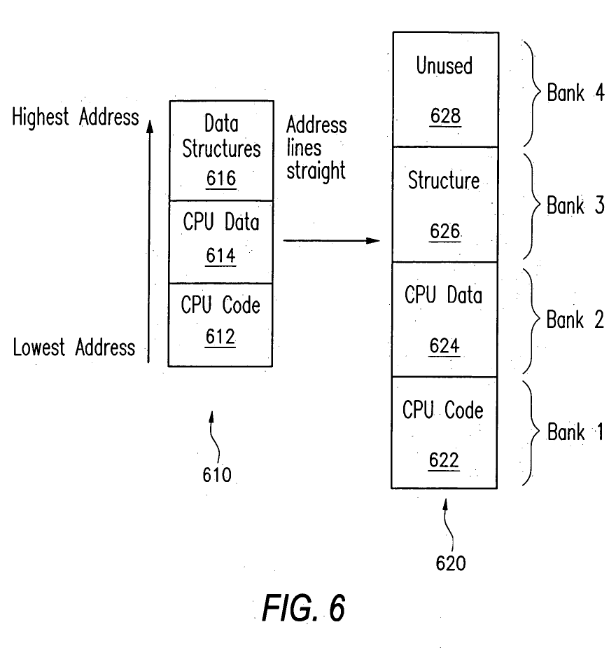

FIG. 6 illustrates a memory map of a straight address line connection, between a processor (e.g., Helium 500 discussed below) and a shared resource (e.g., SDRAM device). A processor may include a logical memory address map 610. In this example, the logical memory address map 610 may include CPU Code 612, CPU Data 614, and Data Structures 616. A shared resource may include a SDRAM device address map 620. According to this example, SDRAM device address map 620 may include CPU Code 622 to Bank 1, CPU Data 624 to Bank 2, Structure 626 to Bank 3 and unused space 628 to Bank 4. As a result, CPU Data accesses may be directed to Bank 2. If, for example, CPU Data generates the most accesses, these accesses will be concentrated to Bank 2. Further, Bank 4 would not be accessed thereby resulting in wasted resources.

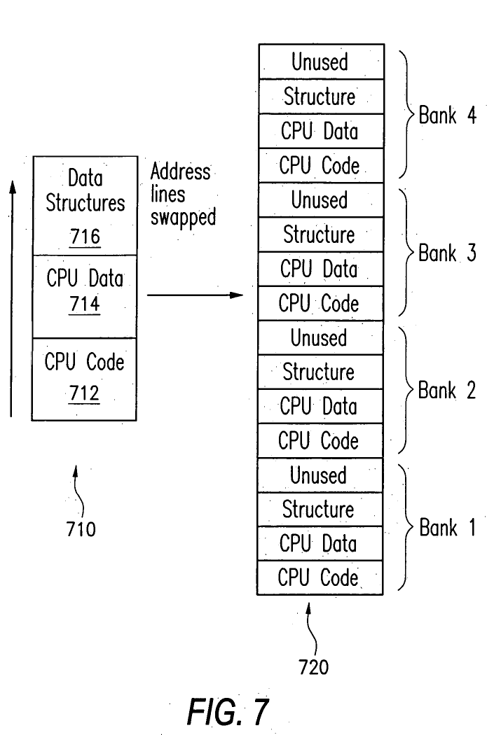

FIG. 7 illustrates a memory map of a crossed address line connection, between a processor (e.g., Helium 500 discussed below) and a shared resource (e.g., SDRAM device) in accordance with an embodiment of the present invention. As shown in FIG. 7, memory cycles are re-ordered to optimize data transfer. In this example, banks of memory are interleaved within the SDRAM device, as shown by 720. In this example, the logical memory address map 710 may include CPU Code 712, CPU Data 714, and Data Structures 716. The logical memory address map 710 may be re-mapped to allow for interleaving, as shown by SDRAM device address map 720. Thus, accesses to multiple maps are evening spread throughout thereby improving interleaving and efficiency.

According to another example, if highest order address lines are swapped with lowest address lines, this may have the effect of putting every adjacent logical memory location in a different bank. This may have a potentially detrimental effect on performance as it may interfere with bursting cycles. Bursting cycles may include highly efficient transfers of small sequential streams of data to the same bank. Generally, bursting cycles should not spread across banks. By swapping the high order address lines with the mid order lines, a compromise may be reached between spreading code evenly across many banks while not interfering with burst mode transfers. In general, performance improvement may be affected by the type of code being run and the granularity of the bank separation.

A processor's address bus has a number (e.g. 28) of address lines used to specify the memory address it wants to access. Normally, these are connected straight through to the corresponding address lines of the memory, so addresses in the processor correspond linearly to locations in the memory (as illustrated by FIGS. 5 and 6). Thus, the lowest addresses will all be in memory bank 1, and higher ones will be in bank 2 then bank 3 and bank 4. Since the processor will typically use only part of its address range, it is likely to use one memory bank, such as Bank 1, much more heavily than the other banks, which gives few opportunities to use interleaving.

A technique of an embodiment of the present invention for evening out the use of some or all the memory banks may involve swap over some of the processor address lines when connecting them to the memory, giving an address mapping similar to map 720, as illustrated in FIG. 7.

For example, a memory size may be size 256 Mbytes, which requires 28 address bits (e.g., called A0 to A27) to address the memory. In the connection from the processor to the memory, certain address lines may be swapped, such as swapping address lines A12 and A13 with A26 and A27, for example. This swapping produces the following exemplary mapping between processor addresses and memory addresses:

| Processor address | Memory address |
|---|---|
| 0x0000000 | 0x0000000 |
| 0x0000fff | 0x0000fff |
| 0x0001000 | 0x4000000 (bit A12 moved to A26) |
| 0x0001fff | 0x4000fff |
| 0x0002000 | 0x8000000 (bit A13 moved to A27) |
| 0x0002fff | 0x8000fff |
| 0x0003000 | 0xc000000 |
| 0x0003fff | 0xc000fff |
| 0x0004000 | 0x0004000 |
| 0x0004fff | 0x0004fff |
| and so on | |

The effect is that as the processor address increases linearly, the memory addresses “jump around” in a way, as illustrated in FIG. 7, so that more even use of all the memory banks may be achieved.

According to an embodiment of the present invention, a re-mapping of a logical address with a physical address is implemented in conjunction with a SDRAM controller's ability to detect accesses to different banks and utilize this opportunity to interleave the accesses together. The re-mapping of logical address lines allows the SDRAM controller a greater probability of successfully interleaving accesses.

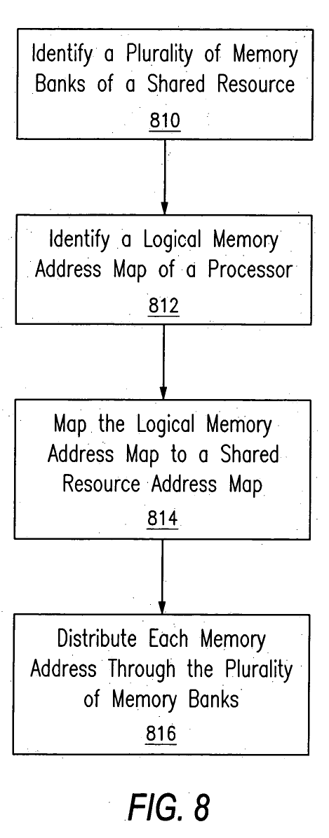

FIG. 8 is an exemplary flowchart illustrating a method for improving access latency, in accordance with an embodiment of the present invention. At step 810, a plurality of different memory banks of a shared resource may be identified. At step 812, a logical memory address map of a processor accessing the shared resource may be identified. At step 814, the logical memory address map may be mapped to a shared resource address map. At step 816, each memory address of the logical memory address may be distributed through the plurality of different memory banks.

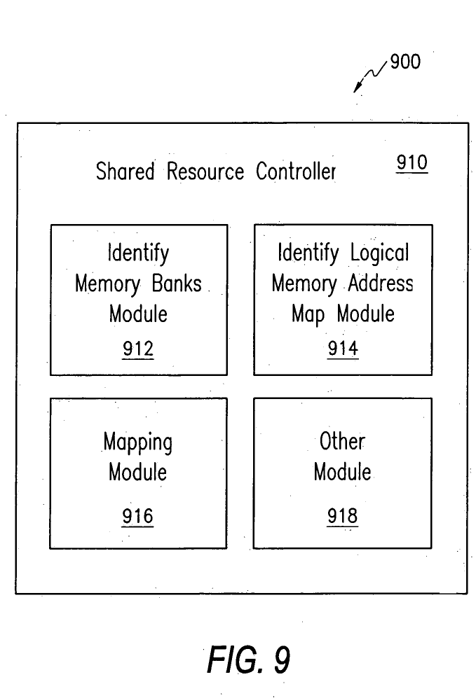

FIG. 9 is a diagram illustrating a system for improving access latency, in accordance with an embodiment of the present invention. A system 900 may include a Share Resource Controller 910 for improving access latency of multiple bank devices. The Shared Resource Controller 910 may include an Identify Memory Banks Module 912, an Identify Logical Memory Address Map Module 914, a Mapping Module 916 and Other Module 918. Identify Memory Banks Module 912 may identify a plurality of different memory banks of a shared resource. Identify Logical Memory Address Map Module 914 may identify a logical memory address map of a processor accessing the shared resource. Mapping Module 916 may map the logical memory address map to a shared resource address map wherein each memory address of the logical memory address is distributed through the plurality of different memory banks.

GlobespanVirata® Corporation's Helium™ 500 communications processor (Helium 500 CP) is a high performance Asynchronous Transfer Mode (ATM) and Internet Protocol (IP) processor. Helium 500 CP offers an extended range of I/O options and features, providing great flexibility as well as an extended choice of operating systems for an application developer. Helium 500 CP uses a dual processor architecture to provide an efficient and flexible solution for a range of applications. The main CPU, the Protocol Processor (PP), runs the operating system and application software. Time critical tasks, such as servicing of I/O ports, ATM switching and ATM traffic shaping are handled by a second processor, the Network Processor (NP). This dual processor design frees the main CPU from constant interrupts, enabling very efficient use of the processor and memory bandwidth for application processing tasks. The Network Processor itself is made more efficient by the inclusion of independent Direct Memory Access (DMA) controller blocks in each of the high-performance I/O blocks. Use of these reduces the NP processing to the start and end of a packet only.

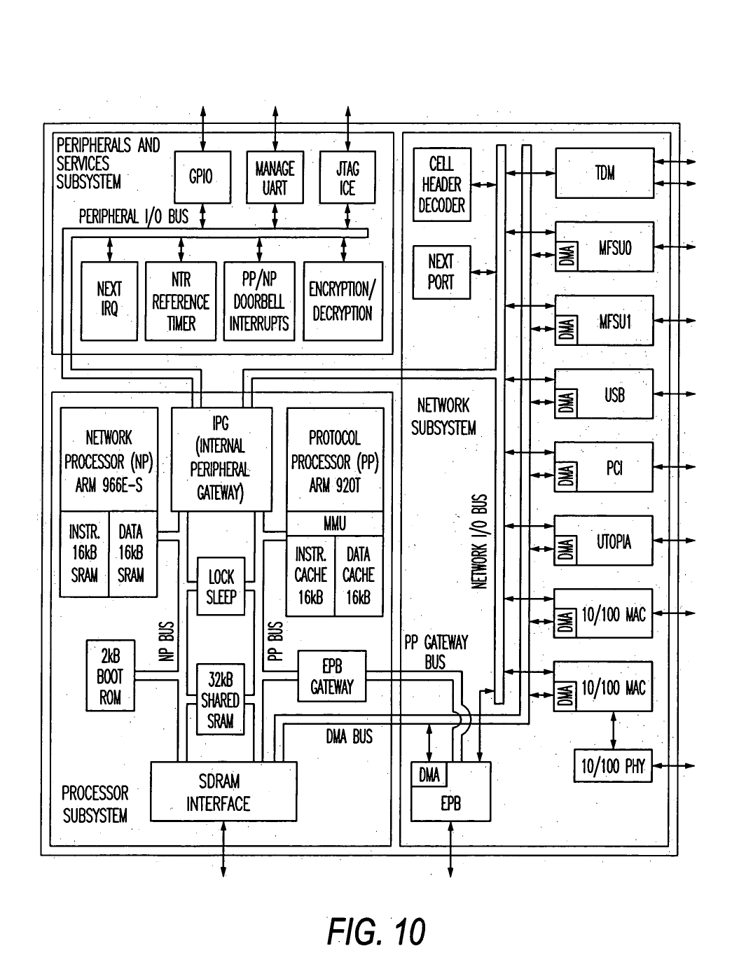

FIG. 10 is a schematic diagram of a hardware architecture in which the inventive aspects of the present invention may be incorporated. In particular, FIG. 10 illustrates a block diagram of Helium 500 CP incorporating the inventive aspects discussed above, in accordance with the present invention. Helium 500 CP has at least three functional subsystems, which include a Processor subsystem, a Network subsystem and a Peripherals and Services subsystem. The Processor subsystem comprises a dual Advanced Reduced Instruction Set Computing (RISC) Machine (ARM®) processor, shared memory and a common Static Random Access Memory (SRAM) interface block. The Network subsystem provides high performance I/O connections and associated services. The Peripherals and Services subsystem provides a programmable General Purpose I/O (GPIO) connection, management and debug connections and additional services for the processors, including hardware encryption/decryption block for optimal network performance. This block also includes the system clocks and timers. These functional sub-systems are linked by high-performance buses, all of which operate at the same clock speed as the processors.

For its main CPU, the Helium 500 CP uses the powerful ARM920T® processor running at 166 or 133 MHz, depending on product variant. Large data and instruction caches and a highly efficient Synchronous Dynamic Random Access Memory (SDRAM) controller further enhance performance. In addition, the inclusion of a memory management unit (MMU) allows the use of a wider choice of operating systems for application development. Applications for the Helium 500 CP can be developed using any of the ATMOS™ operating system, from GlobespanVirata® Corporation; VxWorkS™, from Wind River™, Linux™ and others. For its second processor, the Helium 500 CP uses the high-performance ARM966E-S® processor, also running at 166 or 133 MHz, depending on product variant. For maximum data transfer efficiency, the NP shares SRAM and the SDRAM controller with the PP.

The Helium 500 CP incorporates a wide range of I/O blocks, making it an ideal platform for applications requiring cell, frame and Time Division Multiplexing (TDM) connectivity. In addition to its on-board I/O capabilities, the Helium 500 CP provides expansion ports dedicated to state-of the-art peripheral devices. Its External Peripheral Bus (EPB) supports Motorola™ or Intel™-type peripheral devices, as well as Personal Computer Memory Card International Association (PCMCIA) peripheral devices. For very high performance peripherals, the Helium 500 CP includes a Peripheral Component Interconnect (PCI) expansion bus and system controller. The PCI bus has a direct path to system memory, allowing peripherals to DMA data directly.

Each of the Network I/O blocks, except for the TDM block, includes a dedicated DMA engine. These share a dedicated DMA bus, through which they connect directly to the SDRAM controller. The DMA system allows data transfers between the I/O blocks and external SDRAM to be performed with minimal intervention from the processors.

The Helium 500 communications processor has the following key features: choice of operating system support from ATMOS™ from GlobespanVirata® Corporation, VxWorkS™ from Wind River™; and Linux™; Protocol Processor (PP) as the main CPU: High-performance ARM® 9 with MMU, 16 KB data cache, 16 KB instruction cache; separate ARM® 9 Network Processor (NP) off-loads time-critical tasks from PP, 32 KB private “tightly coupled” SRAM onchip: 16 KB data, 16 KB instruction space; product variants with 166 MHz and 133 MHz processor speeds, memory systems designed to optimize throughput of data: additional 32 KB SRAM shared between the two processors, high performance SDRAM controller, shared by the two processors, operates synchronously with processors; supports up to 128 MB external DRAM; high-performance DMA systems, optimized for efficient handling of communications data: each high-bandwidth I/O block has its own dedicated DMA engine, a common full-speed 32 bit bus links the DMA engines directly to the SDRAM controller; in normal operation, the NP will initiate a DMA transfer where no further NP processing is required until the transfer has completed, functions such as checksum calculation and byte alignment can be performed while the data is being transferred, Nextport logic block determines which I/O port service request has the highest priority, removing need for any polling of I/O ports by the processor, similarly, a Next Interrupt Request (IRQ) block prioritizes outstanding IRQs without processor intervention; dual 10/100 Mb/s Ethernet Media Access Controllers (MACs); Encryption/Decryption hardware accelerator (with Internet Protocol Security (IPSec) support), supported by hardware random number generator: encrypts and decrypts data as defined in FIBS BUS 81, single or triple Data Encryption Standard (DES) modes; supports Electronic Code Book (ECB), Cipher Block Chaining (CBC), Output Feedback (cryptography) (OFB)-64, incorporates Secure Hashing Algorithm according to FIPS PUB 180-1 (SHA-1) hardware assist function; two high-speed multi-function serial units (MFSUs), each of which is configured to operate in one of three modes: High-Level Data Link Control (HDLC) mode conforms to q.921 and ISO/IEC 2209:1993, supports bus mode, V.35 and X.21 fixed links operating at up to 50 Mb/s, hardware support for 16 and 32 bit Frame Checking Sequence (FCS); I.432 Mode is in accordance with International Telecommunication Union-Telecommunications (ITU-T) I.432 interface standard at 50 Mb/s data rate; High-speed Serial Universal Asynchronous Receiver and Transmitter (UART) mode, supporting both 3-wire and 5-wire interfaces (software or hardware flow control) at 1.5 Mb/s data rate, suitable for connection to Bluetooth devices; TDM block provides two independent TDM interfaces with flexible HDLC controllers, each offering data rate up to 8 Mb/s; up to 256 programmable time-slots, up to 32 simultaneous HDLC streams, with single or multiple time-slots and programmable number of bits per slot; ability to support “quad” framer devices (carrying up to four T1/E1 channels); Universal Test and Operations Physical Interface for ATM (UTOPIA) master/slave port offers UTOPIA level 1 or 2 ports, master or slave operation, provides up to 31 ports, first 8 ports can be configured for high-speed operation; Network Timing Reference (NTR) recovery function, can also provide local network clock generation; PCI expansion bus for high-speed, flexible peripheral connection: 32 bit, 33 MHz bus, PCI master or slave operation, in-built arbiter with support for up to two peripheral devices for operation in master mode, PCI Rev 2.2 complaint; External peripheral bus (EPB) for co-processor or peripheral expansion: supports 8, 16 and 32 bit bus widths, offers support for i960, Motorola, Intel and PCMCIA bus formats, programmable strobes allows support for other formats; Universal Serial Bus (USB) 1.1 slave port operates at 12 Mhz; Programmable GPIO block with up to 64 I/O pins available, each configurable as input or output, allows interfacing to local device (e.g., for driving indicators or sensing switches); support for IEEE 1149.1 boundary scan and ARM® In-Circuit Emulator (ICE) debugger; Compatible with GlobespanVirata Corporation Helium family of products and IP Service Operating System (ISOS) software; designed throughout for low-power operation, many operational blocks can be put into standby mode to save power.

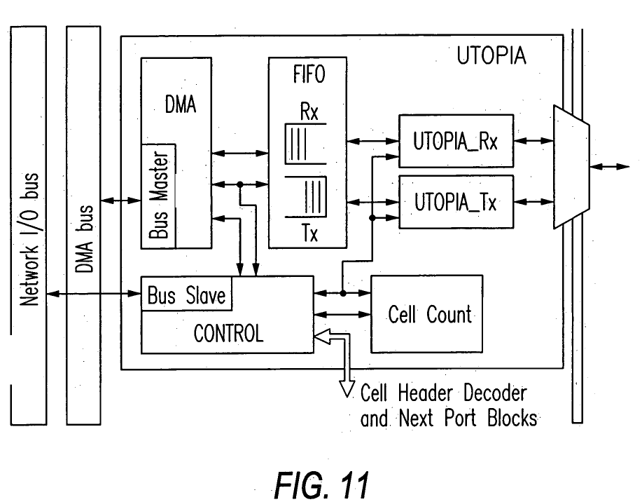

FIG. 11 is a schematic diagram of a hardware architecture in which the inventive aspects of the present invention may be incorporated. In particular, FIG. 11 is a UTOPIA block functional overview incorporating the inventive features discussed in detail above. The Helium 500 CP provides a single UTOPIA interface which can operate in the following four modes: UTOPIA level 2 Master (L2M) up to 31 ports; UTOPIA Level 2 Slave (L2S) single port (port number between 0 and 30); UTOPIA Level 1 Master (L1M) single port (port 0); and UTOPIA level 1 slave (L1S) single port (port 0).

As shown in FIG. 11, the main data path through the block passes (in the reverse direction) from the external connections, through the UTOPIA Rx processor, to the First In First Out (FIFO) block. The DMA engine, which forms part of the block, transfers data from the FIFO onto the DMA bus and then directly into SDRAM. The transmit data path is simply the reverse of this, passing from the FIFOs through the UTOPIA Tx processor block. In addition, the UTOPIA block control logic is connected to the Network I/O bus, and can also access the FIFOs. A cell counter unit is also provided; this tracks the number of cells transmitted and received on each port. The block provides highly-flexible support for the prioritization of some ports for high-speed operation. Separate FIFOs are provided for Transmit and Receive data. The organization of the FIFOs depends on the operating mode of the block; however each active port is always provided with at least a single cell (e.g., 13-word) buffer. The FIFO hardware provides synchronization between the different clock domains of the UTOPIA block, where this is required.

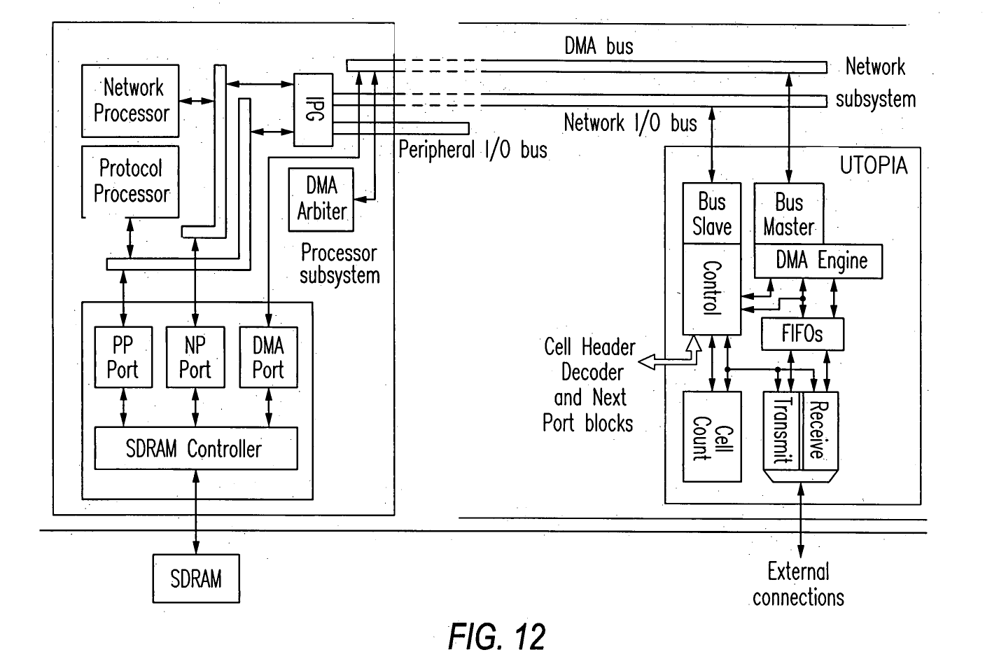

FIG. 12 is a schematic diagram of a hardware architecture in which the inventive aspects of the present invention may be incorporated. In particular, FIG. 12 illustrates the relation of the UTOPIA block to the Helium 500 CP architecture. This diagram indicates how the UTOPIA block's DMA engine transfers data directly to external SDRAM, via the DMA bus and the SDRAM controller, without any intervention from the processors. It also indicates the direct connections between the UTOPIA block and the Next Port and Cell Header Decoder blocks of the Network subsystem.

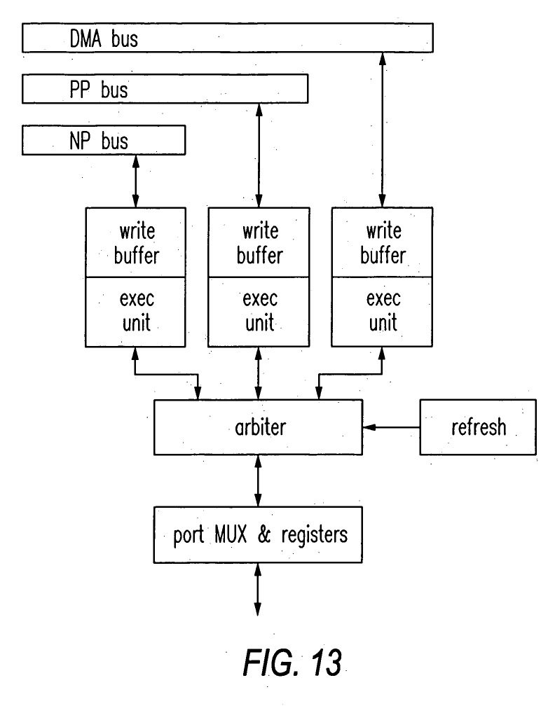

FIG. 13 is a schematic diagram of a hardware architecture in which the inventive aspects of the present invention may be incorporated. In particular, FIG. 13 illustrates a SDRAM block diagram. The SDRAM controller provides a high-performance interface to external SDRAMs for code and data storage. It operates at the processor core clock frequency of 166 or 133 MHz, and is compatible with the Joint Electronic Device Engineering Counsel (JEDEC) standard JED2421 for interfacing to synchronous DRAMs. The controller has three internal ports allowing the DMA controller, the NP and the PP to access SDRAM via separate internal buses. The controller features independent write data and address buffering on each port (e.g., 16 word data buffer on each port (DMA, NP and PP ports); 1 address buffer per port); intelligent arbitration between the three ports where the arbitration scheme dynamically adjusts to the load conditions and also guarantees maximum latency requirements at each port; and advanced SDRAM interleaving where the SDRAM controller re-orders memory cycles to optimize data transfer. It does this by automatically interleaving banks of memory with in the SDRAM devices. The overhead of preparing one bank is hidden during data movement to the other. This process is entirely transparent to the user. Other features include data coherency guarantee where the controller guarantees data coherency between ports (e.g., data in a write buffer on one port can be accessed by a read from another port) and support for memory devices sizes of 64 Mb, 128 Mb and 256 Mb, each of which can be 8, 16 or 32 bits wide, the maximum memory that can be connected is 4×256 Mb (128 MB). Generally, access to the external SDRAM is 32-bits wide. Another feature includes a power down mode where a low power mode drastically reduces the power consumed by external SDRAM devices.

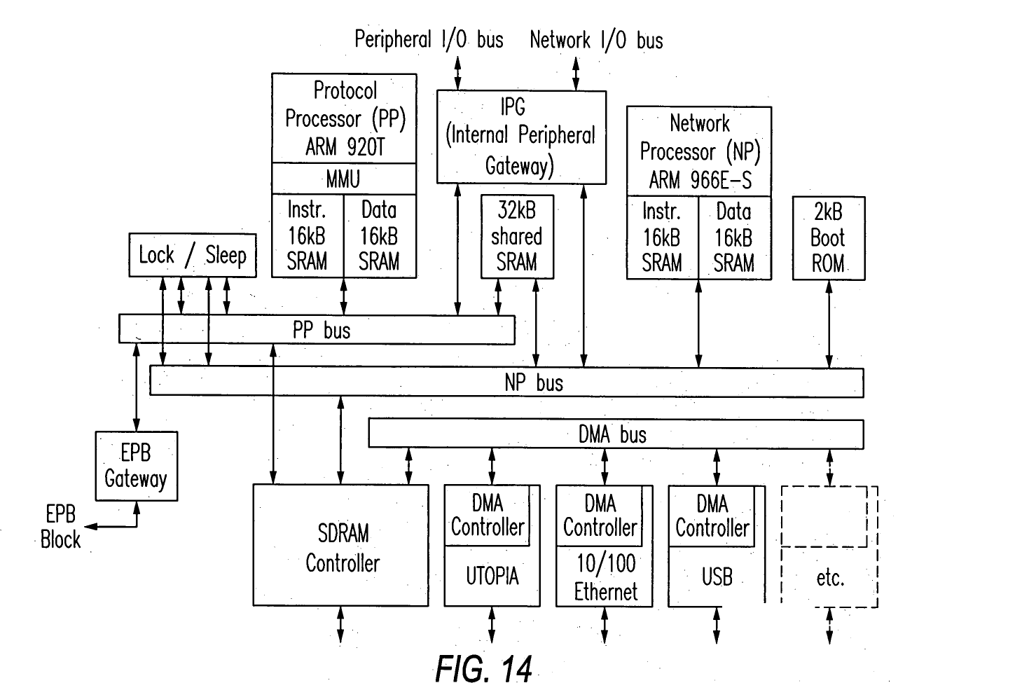

FIG. 14 is a schematic diagram of a hardware architecture in which the inventive aspects of the present invention may be incorporated. In particular, FIG. 14 illustrates a core system including processors and DMAs. A principle use of the DMA system is for the NP to transfer data packets and cells between SDRAM buffers and network ports. The DMA system may include a DMA engine within each of the high performance I/O blocks and a dedicated DMA bus linking these engines to the SDRAM controller. This enables the NP to interleave operations efficiently on different devices without being stalled by SDRAM accesses. The DMA channels carry out functions such as checksum calculation and byte alignment as the data is transferred. The PP may also make use of DMA channels, for example to access devices attached to the EFB.

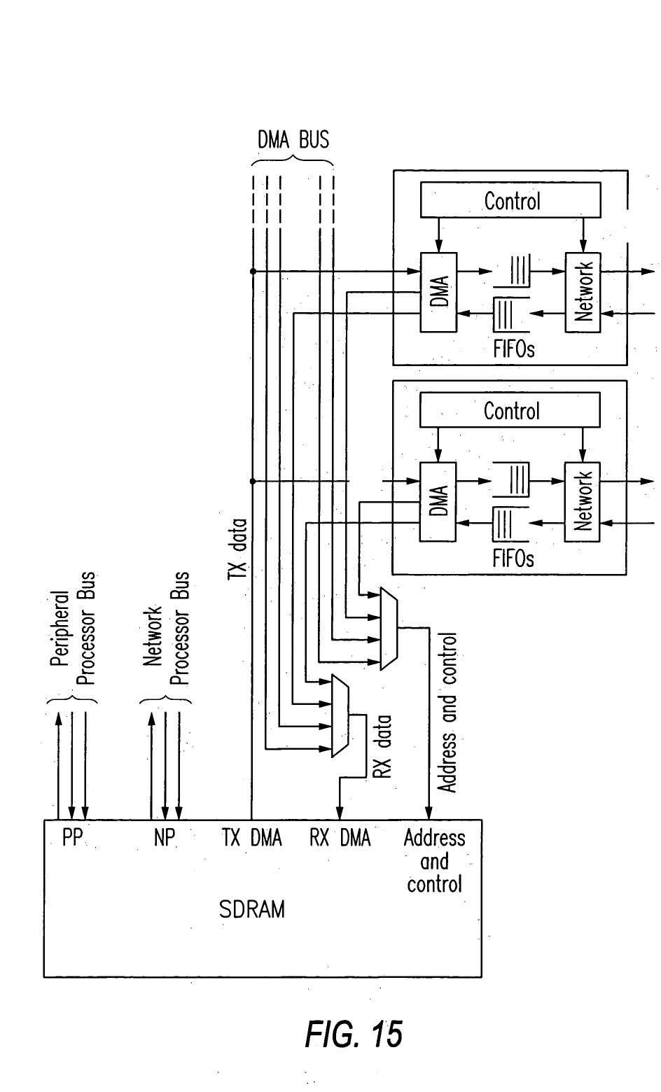

FIG. 15 is a schematic diagram of a hardware architecture in which the inventive aspects of the present invention may be incorporated. In particular, FIG. 15 is a DMA block diagram. The DMA system reduces the reliance on NP when transferring data between high-speed I/O modules and the SDRAM memory. The system includes a DMA controller within each of the high-speed I/O modules, connecting directly to the Transmit and Receive FIFOs within the module; a dedicated DMA port on the SDRAM controller; and a dedicated high-speed 32-bit DMA bus, linking the DMA controllers to the SDRAM controller. DMA transfers between the network module FIFOs and the SDRAM take place in parallel with other NP operations; NP processing is required only at the start and end of the packet or cell. Each DMA controller is able to discard packets that do not need to be received. A single DMA transfer across the bus (e.g., a burst) is between one and 16 words. The 16 word limit prevents any device from “hogging” the DMA bus. Where larger DMA data transfers are required they are split into multiple 16-word bursts, automatically. Write performance is enhanced by buffering in the SDRAM controller. The addressable memory range of the DMA controllers is 256 MB, although the SDRAM controller limits the usable address range of 128 MB.

The DMA system illustrated in FIG. 15 includes two exemplary I/O blocks. Additional I/O blocks may be implemented. The control block without each of the I/O blocks is connected to the Network I/O. For clarify, these connections have been omitted from the diagram. The SDRAM controller shown in FIG. 15 provides write buffering on its input from the DMA bus, optimizing the performance of write operations.

Data transfers within the Helium 500 CP will normally take place under the control of the Network Processor (NP), responding to service requests provided through the Next Port mechanism. The Helium 500 CP allows other modes of operation; for example, DMA transfers could be driven by interrupts from the I/O ports. DMA transfers involve the inter-operation of the I/O block and the DMA block. Each I/O block which uses the DMA engine has two groups of registers, the I/O block-specific registers and the DMA registers. The I/O block-specific registers control data transfers (e.g., transmission and reception) between the I/O block and the external network and may be highly block specific. The DMA registers control DMA data transfer between the I/O block and the SDRAM and are essentially the same for each block, although not all of the DMA registers are provided in all I/O blocks. To set up a network data transfer (e.g., transmit or receive), I/O block-specific registers will be used to set up the transmit or receive operations and the DMA registers will be used to set up the data transfer between the I/O block and the SDRAM. Data is transferred directly between SDRAM and the FIFOs of the I/O block, under the control of the DMA engine and without any intervention from the NP. Burst transfers across the DMA bus are limited to a maximum of 16 words; if the requested transfer is longer than this it will be split into multiple 16-word bus transfers, and DMA bus arbitration will take place after each burst. With transmit operations, signaling within the DMA system ensures that data is only transferred across the DMA bus if the FIFO has space to receive it. The I/O block is responsible for detecting the recovering from data over- or under-run conditions, and may abort the DMA transfer (e.g., if it is unable to transmit data from the FIFO to free up space for the requested data transfer). When the entire data transfer has been completed the DMA block raises a service request to indicate the fact. The I/O block may then need to perform additional processing to complete the operation.

While the foregoing description includes many details and specificities, it is to be understood that these have been included for purposes of explanation only, and are not to be interpreted as limitations of the present invention. Many modifications to the embodiments described above can be made without departing from the spirit and scope of the invention.

The present invention is not to be limited in scope by the specific embodiments described herein. Indeed, various modifications of the present invention, in addition to those described herein, will be apparent to those of ordinary skill in the art from the foregoing description and accompanying drawings. Thus, such modifications are intended to fall within the scope of the following appended claims. Further, although the present invention has been described herein in the context of a particular implementation in a particular environment for a particular purpose, those of ordinary skill in the art will recognize that its usefulness is not limited thereto and that the present invention can be beneficially implemented in any number of environments for any number of purposes. Accordingly, the claims set forth below should be construed in view of the full breath and spirit of the present invention as disclosed herein.

1. A method for improving access latency of multiple bank devices, the method comprising the steps of:
identifying a plurality of different memory banks of a shared resource;
identifying a logical memory address map of a processor accessing the shared resource; and
mapping the logical memory address map to a shared resource address map wherein each memory address of the logical memory address is distributed through the plurality of different memory banks.

2. The method of claim 1, wherein each memory address of the logical memory address map accesses each of the plurality of memory banks.

3. The method of claim 1, wherein each access of each of the plurality of different memory banks overlaps each other.

4. The method of claim 1, wherein bursting cycles are not interfered.

5. The method of claim 4, wherein the bursting cycles include efficient transfers of small sequential streams of data to a same memory bank.

6. The method of claim 1, wherein interleave accesses are improved.

7. The method of claim 1, wherein the plurality of memory banks comprise at least four different memory banks.

8. The method of claim 1, wherein the shared resource comprises one or more of DRAM, SDRAM and DDR.

9. The method of claim 1, wherein the step of mapping further comprises the step of:
exchanging higher order address lines with mid-order address lines.

10. The method of claim 1, wherein the processor's local code is spread across the plurality of memory banks.

11. A system for improving access latency of multiple bank devices, the system comprising:
an identifying memory banks module for identifying a plurality of different memory banks of a shared resource;
an identifying address map module for identifying a logical memory address map of a processor accessing the shared resource; and
a mapping module for mapping the logical memory address map to a shared resource address map wherein each memory address of the logical memory address is distributed through the plurality of different memory banks.

12. The system of claim 11, wherein each memory address of the logical memory address map accesses each of the plurality of memory banks.

13. The system of claim 11, wherein each access of each of the plurality of different memory banks overlaps each other.

14. The system of claim 11, wherein bursting cycles are not interfered.

15. The system of claim 14, wherein the bursting cycles include efficient transfers of small sequential streams of data to a same memory bank.

16. The system of claim 11, wherein interleave accesses are improved.

17. The system of claim 11, wherein the plurality of memory banks comprise at least four different memory banks.

18. The system of claim 11, wherein the shared resource comprises one or more of DRAM, SDRAM and DDR.

19. The system of claim 11, wherein the mapping module further exchanges higher order address lines with mid-order address lines.

20. The system of claim 11, wherein the processor's local code is spread across the plurality of memory banks.

21. The method of claim 1, wherein the steps are performed at a customer premise equipment.

22. The method of claim 1, wherein the steps are performed at a central office.

23. The system of claim 11, wherein the system comprises a customer premise equipment.

24. The system of claim 11, wherein the system comprises a central office.

25. A computer readable medium, the computer readable medium comprising a set of instructions for improving access latency of multiple bank devices and being adapted to manipulate a processor to:
identify a plurality of different memory banks of a shared resource;
identify a logical memory address map of a processor accessing the shared resource; and
map the logical memory address map to a shared resource address map wherein each memory address of the logical memory address is distributed through the plurality of different memory banks.
